(19) United States
(12) Patent Application Publication
(10) Pub. No.: US 2015/0333070 A1
(43) Pub. Date: Nov. 19, 2015

(54) SEMICONDUCTOR DEVICE MANUFACTURING METHOD

(71) Applicants: Kanta SAINO, (US); Takeshi NAGAI, (US); PS4 LUXCO S.A.R.L., Luxembourg (LU)

(72) Inventors: Kanta Saino, Tokyo (JP); Takeshi Nagai, Tokyo (JP)

(21) Appl. No.: 14/655,179

(22) PCT Filed: Dec. 24, 2013
(86) PCT No.: PCT/JP2013/084437

§ 371 Date: Jun. 24, 2015

(30) Foreign Application Priority Data
Dec. 25, 2012 (JP) 2012-280524

(51) Int. Cl. H01L 27/108

(52) U.S. Cl. CPC H01L 27/10844

(57) ABSTRACT

The present invention provides a semiconductor device manufacturing method that reduces contact resistances in a memory cell region. This semiconductor device manufacturing method includes: a step wherein a gate insulating film and gate electrodes are formed in a second region; a step wherein a first liner film is formed so as to cover wires and the first gate electrodes in a first region and the second region; a step wherein first gate sidewalls are formed by etching back the first liner film in the second region; a step wherein a second liner film is formed so as to cover the first liner film in the first region while covering the gate electrodes in the second region; a step wherein second gate sidewalls adjoining the first gate sidewalls are formed by etching back the second liner film in the second region; a step wherein an impurity diffusion region is formed by injecting impurities into a semiconductor substrate in the second region; a step wherein the impurity diffusion region is activated by means of a thermal treatment; and a step wherein the second liner film is removed from the first region after the thermal treatment.

### TECHNICAL FIELD

### Notice Regarding Related Application

The present invention is based upon the priority claim of Japanese patent application No. 2012-280524 (filed on Dec. 25, 2012), the disclosure of which is incorporated herein in its entirety by reference thereto.

The present invention relates to a semiconductor device, and in particular relates to a method of manufacturing a field-effect transistor in which a metal gate electrode is formed on a gate insulating film containing a high dielectric-constant (High-k) film.

### BACKGROUND ART

One type of semiconductor device is a DRAM (Dynamic Random Access Memory). In a DRAM there are a memory cell region in which memory elements are arranged, and a peripheral circuit region which controls the memory elements, for example.

Patent literature article 1 discloses a transistor manufacturing technique in which the thicknesses of the side walls of MOS transistors are made to differ between the memory cell region and the peripheral circuit region in order to prevent channel shortening and a deterioration in the electrical properties.

Patent literature article 2 discloses a semiconductor device which, in order to avoid line breaks and operational delays, has a metal laminated wiring line which extends across the memory cell region and the peripheral circuit region, and which forms a bit line in the memory cell region, and forms part of a peripheral circuit wiring line and part of a gate electrode in the peripheral circuit region.

Patent literature article 3 discloses introducing oxygen into a gate dielectric film comprising a high dielectric-constant (High-k) film, in order to reduce the transistor threshold.

### PATENT LITERATURE

Patent literature article 1: Japanese Patent Kokai 2012-059880
Patent literature article 2: Japanese Patent Kokai 2012-099793
Patent literature article 3: Japanese Patent Kokai 2009-283906

### SUMMARY OF THE INVENTION

### Problems to be Resolved by the Invention

The content of each of the abovementioned patent literature articles is incorporated herein by reference. The following analysis is provided from the viewpoint of the present invention.

DRAMs are manufactured using self-aligned contacts (SAC) to minimize the memory size. Here, a method of manufacturing a semiconductor device in which the bit lines in the memory cell region and the gate electrodes in the peripheral circuit region are formed simultaneously will be described. FIG. 11 to FIG. 14 are schematic process diagrams used to describe a method of manufacturing a semiconductor device according to the background art. In FIG. 11 to FIG. 14, the left side illustrates a memory cell region A, and the right side illustrates a peripheral circuit region B. FIG. 11 to FIG. 14 illustrate a cross section perpendicular to bit lines in the memory cell region and gate electrodes in the peripheral circuit region.

In FIG. 11, element isolation regions 902 are formed in a semiconductor substrate 901. In the memory cell region A, MC (Memory Cell) gate insulating films (which are not shown in the drawings) and embedded word lines (which are not shown in the drawings) are formed. A first interlayer insulating film 911 with bit lines 920 thereon is formed on the semiconductor substrate 901 in the memory cell region A, and PC (Peripheral Circuit) gate insulating films 931 and PC gate electrodes 930 are formed on the semiconductor substrate 901 in the peripheral circuit region B. A first liner film 981 is then formed on the semiconductor substrate 901 in such a way as to cover the bit lines 920 and the PC gate electrodes 930 (FIG. 11).

A mask (which is not shown in the drawings) is then formed on the memory cell region A. The first liner film 981 on the peripheral circuit region B is then etched back to form first PC side walls 936 on the PC gate electrodes 930 in the peripheral circuit region B. An impurity is then implanted into the semiconductor substrate 901, using the PC gate electrodes 930 and the first PC side walls 936 as a mask, to form LDD (Lightly Doped Drain) regions 906 in the peripheral circuit region B (FIG. 12).

A second liner film 982 is then formed on the semiconductor substrate 901 and the first liner film 981 in such a way as to cover the bit lines 920 and the PC gate electrodes 930 (FIG. 13).

A mask (which is not shown in the drawings) is then formed on the peripheral circuit region B. The second liner film 982 in the memory cell region A is then removed. The first liner film 981 in the memory cell region A is then etched back to form first MC side walls 924 on the bit lines 920.

A mask (which is not shown in the drawings) is then formed on the memory cell region A. The second liner film 982 on the peripheral circuit region B is then etched back to form second PC side walls 937 on the PC gate electrodes 930 in the peripheral circuit region B. An impurity is then implanted into the semiconductor substrate 901 in the peripheral circuit region B, using the PC gate electrodes 930, the first PC side walls 936 and the second PC side walls 937 as a mask, to form PC source/drain regions 907 (FIG. 14).

Heat treatment is then carried out to activate the PC source/drain regions 907 in the peripheral circuit region B. However, this also causes the memory cell region A to be heat treated. FIG. 15 is an enlarged schematic cross-sectional view of the memory cell region A after heat treatment.

Finally, capacitor contact plugs are formed between the bit lines 920 in the memory cell region A. The first MC side walls 924 fulfill the role of insulating films which prevent short-circuiting between the bit lines 920 and the capacitor contacts. Meanwhile, in order to prevent an increase in the contact resistance, the surface area of the openings used to form the capacitor contact plugs must be maintained at or above a certain surface area. The thickness of the first MC side walls 924 must therefore be at most equal to a certain thickness, for example 5 nm. However, because heat treatment is carried out with the thin first MC side walls 924 in an exposed condition, parts of the bit lines 920 covered by the first MC side walls 924 also become oxidized. If, for example, the bit lines 920 comprise a laminated body of tungsten (W), tungsten nitride (WN) and tungsten silicide (WSi), with polysilicon formed on said laminated body, parts of the laminated body and the polysilicon (oxidized parts 921a and 922a illustrated in FIG. 15) become oxidized. Further, the impurity implanted into the polysilicon diffuses outward. The bit line resistance, the interfacial resistance and the contact resistance thus increase. Further, the volume increases if the tungsten is oxidized abnormally. As a result, the surface area of the openings for the capacitor contact plugs decreases, causing the contact resistance to increase.

Further, in the process described hereinabove, the thickness of the first MC side walls 924 and the thickness of the first PC side walls 936 cannot be controlled independently. That is to say, the thicknesses of the first MC side walls 924 and the first PC side walls 936 are determined depending on the required thickness of the first MC side walls 924. However, if an HKMG (High-k/Metal Gate), in which a high-k film is used as the gate insulating film, is employed, then if the first PC side walls are thin, oxidant penetrates into the HKMG, and the effective work function (EWF) of the HKMG changes significantly. Therefore the threshold voltage of the transistors in the peripheral circuit region B varies significantly depending on the thickness of the first MC side walls 924.

### Means of Overcoming the Problems

One aspect of the present invention provides a method of manufacturing a semiconductor device, comprising: a step of forming a wiring line in a first region of a semiconductor device; a step of forming a first gate insulating film in a second region of the semiconductor device; a step of forming a first gate electrode on the first gate insulating film; a step of forming a first liner film in the first region and the second region in such a way as to cover the wiring line and the first gate electrode; a step of etching back the first liner film in the second region to form a first gate side wall; a step of forming a second liner film in such a way as to cover the first liner film in the first region and in such a way as to cover the first gate electrode in the second region; a step of etching back the second liner film in the second region to form a second gate side wall adjacent to the first gate side wall; a step of implanting a first impurity into the semiconductor substrate in the second region to form a first impurity-diffused region; a step of carrying out heat treatment to activate the first impurity-diffused region; and a step of removing the second liner film in the first region after the heat treatment has been carried out.

### BRIEF EXPLANATION OF THE DRAWINGS

FIG. 1 is a schematic plan view illustrating one example of a semiconductor device that can be manufactured.

FIG. 2 is a schematic cross-sectional view through the line II-II in FIG. 1.

FIG. 3 is a schematic process diagram used to describe a method of manufacturing a semiconductor device according to a first mode of embodiment.

FIG. 4 is a schematic process diagram used to describe the method of manufacturing a semiconductor device according to the first mode of embodiment.

FIG. 5 is a schematic process diagram used to describe the method of manufacturing a semiconductor device according to the first mode of embodiment.

FIG. 6 is a schematic process diagram used to describe the method of manufacturing a semiconductor device according to the first mode of embodiment.

FIG. 7 is a schematic process diagram used to describe the method of manufacturing a semiconductor device according to the first mode of embodiment.

FIG. 8 is a schematic process diagram used to describe the method of manufacturing a semiconductor device according to the first mode of embodiment.

FIG. 9 is a schematic process diagram used to describe the method of manufacturing a semiconductor device according to the first mode of embodiment.

FIG. 10 is a schematic process diagram used to describe a method of manufacturing a semiconductor device according to a second mode of embodiment.

FIG. 11 is a schematic process diagram used to describe a method of manufacturing a semiconductor device according to the background art.

FIG. 12 is a schematic process diagram used to describe the method of manufacturing a semiconductor device according to the background art.

FIG. 13 is a schematic process diagram used to describe the method of manufacturing a semiconductor device according to the background art.

FIG. 14 is a schematic process diagram used to describe the method of manufacturing a semiconductor device according to the background art.

FIG. 15 is an enlarged schematic cross-sectional view of a memory cell region after heat treatment, in the background art.

### MODES OF EMBODYING THE INVENTION

Preferred modes of the abovementioned aspect will now be described.

According to a preferred mode of the first aspect, the method of manufacturing a semiconductor device additionally comprises, after the first liner film has been formed, a step of thinning the first liner film in the first region.

According to a preferred mode of the first aspect, the method of manufacturing a semiconductor device additionally comprises, after the first gate side wall has been formed, a step of thinning the first liner film in the first region.

According to a preferred mode of the first aspect, the method of manufacturing a semiconductor device additionally comprises, after the second gate side wall has been formed, a step of thinning the first liner film in the first region.

According to a preferred mode of the first aspect, the method of manufacturing a semiconductor device additionally comprises: a step of etching back the first liner film in the first region to form a first wiring line side wall; a step of forming a third liner film on the semiconductor substrate in the first region and the second region in such a way as to cover the wiring line and the first gate electrode; a step of etching back the third liner film in the first region to form a second wiring line side wall adjacent to the first wiring line side wall; and a step of etching back the third liner film in the second region to form a third gate side wall adjacent to the second gate side wall.

According to a preferred mode of the first aspect, the method of manufacturing a semiconductor device additionally comprises a step of forming a first contact plug between the adjacent second wiring line side walls, electrically connected to the semiconductor substrate.

According to a preferred mode of the first aspect, at least part of the wiring line and the first gate electrode are formed using the same step.

According to a preferred mode of the first aspect, the step of forming the wiring line and the first gate electrode comprises: a step of forming a first conductor layer on the semiconductor substrate; a step of forming an insulating layer on the conductor layer; and a step of patterning the first gate insulating film, the first conductor layer and the insulating layer into a desired shape.

According to a preferred mode of the first aspect, the step of forming the wiring line and the first gate electrode additionally comprises, before the step of forming the first conductor layer, a step of forming a second conductor layer on the semiconductor substrate in the second region. In the second region, the first conductor layer is formed on the second conductor layer.

According to a preferred mode of the first aspect, the method of manufacturing a semiconductor device additionally comprises: a step of forming a first interlayer insulating film on the semiconductor substrate in the first region; and a step of forming a first contact plug that penetrates through the first interlayer insulating film and is electrically connected to the semiconductor substrate. The wiring line is formed on the first interlayer insulating film in such a way as to be electrically connected to the first contact plug.

According to a preferred mode of the first aspect, the method of manufacturing a semiconductor device additionally comprises, after the second liner film has been removed, a step of etching the first interlayer insulating film in such a way as to expose the semiconductor substrate.

According to a preferred mode of the first aspect, the method of manufacturing a semiconductor device additionally comprises, after the first liner film has been formed and before the step of forming the second liner film, a step of implanting a second impurity into the semiconductor substrate in the second region to form a second impurity-diffused region.

According to a preferred mode of the first aspect, the first liner film is a silicon nitride film or a silicon oxynitride film.

According to a preferred mode of the first aspect, the second liner film is a silicon dioxide film.

According to a preferred mode of the first aspect, the method of manufacturing a semiconductor device additionally comprises: a step of forming a groove in the semiconductor substrate in the first region; a step of implanting a third impurity into the semiconductor substrate in the first region to form a third impurity-diffused region; a step of forming a second gate insulating film in the groove; and a step of forming a second gate electrode on the second gate insulating film.

In the following description, drawing reference codes are appended to aid understanding of the invention, and the present invention is not intended to be limited to the modes illustrated in the drawings. Further, the ordinal numbers set forth in the scope of the patent claims do not correspond to the ordinal numbers in the following description.

A method of manufacturing a semiconductor device according to a first mode of embodiment will be described.

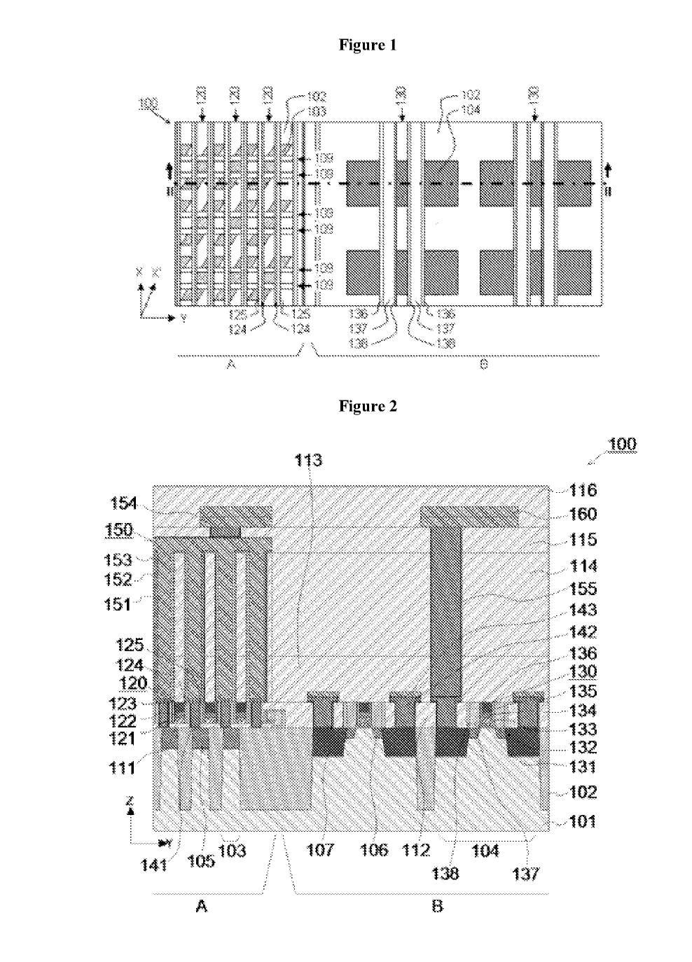

An example of a semiconductor device that can be manufactured by means of said manufacturing method will first be described. FIG. 1 is a schematic plan view of a semiconductor device that can be manufactured by means of the method of manufacturing a semiconductor device according to the first mode of embodiment. FIG. 2 is a schematic cross-sectional view through the line II-II in FIG. 1. FIG. 1 is a drawing used to facilitate understanding of the positional relationships between each element. FIG. 1 depicts only some of the elements. Further, in FIG. 1, the locations in which bit lines 120 and PC gate electrodes 130 are formed are indicated by arrows. Hatching has been applied to the active regions illustrated in FIG. 1.

In the mode illustrated in FIG. 1 and FIG. 2, a DRAM is depicted as an example of a semiconductor device 100. The semiconductor device 100 comprises a memory cell region A, on the left in the drawing, and a peripheral circuit region B, on the right in the drawing.

The semiconductor device 100 is provided with a semiconductor substrate 101 and element isolation regions 102 which demarcate active regions. Memory cell (referred to as ‘MC’ hereinafter.) active regions 103 are formed in the memory cell region A. Peripheral circuit (referred to as ‘PC’ hereinafter.) active regions 104 are formed in the peripheral circuit region B. In the memory cell region A, the MC active regions 103 are formed in the shape of parallelograms. A plurality of MC active regions 103 are arranged parallel to one another in the Y-direction. Further, the plurality of MC active regions 103 are arranged in such a way that the Y-direction arrays are displaced parallel to one another in an X′ direction which is at a certain angle to the X-direction and the Y-direction, in other words the MC active regions 103 are aligned in such a way as to form dashed lines extending in the X′-direction. In the peripheral circuit region B, the PC active regions 104 are formed in the shape of rectangles. A plurality of PC active regions 104 are arranged in a lattice formation.

The semiconductor substrate 100 is additionally provided with a first interlayer insulating film 111 formed on the semiconductor substrate 101, a second interlayer insulating film 112 formed on the semiconductor substrate 101, a stopper film 113 formed on the second interlayer insulating film 112, a third interlayer insulating film 114 formed on the stopper film 113, a fourth interlayer insulating film 115 formed on the third interlayer insulating film 114 and a protective insulating film 116 formed on the fourth interlayer insulating film 115.

The memory cell region A will first be described. In the memory cell region A, the semiconductor device 100 is provided with embedded word lines 109 which are embedded in grooves formed in the semiconductor substrate 101, MC gate insulating films (which are not shown in the drawings) embedded in said grooves, and MC source/drain regions 105 formed in the semiconductor substrate 101. Further, the semiconductor device 100 is also provided with bit lines 120 formed on the first interlayer insulating film 111, bit contact plugs (which are not shown in the drawings) which electrically connect the bit lines 120 to the MC active regions 103, first MC side walls 124 and second MC side walls 125 formed as side walls on both sides of the bit lines 120, and capacitor contact plugs 141 which are formed between adjacent bit lines 120, in other words between the second MC side walls 125, and which are electrically connected to the MC source/drain regions 105. The bit lines 120 and the capacitor contact plugs 141 are formed in the layer comprising the first interlayer insulating film 111 and the second interlayer insulating film 112.

The embedded word lines 109 extend in the Y-direction in the drawings. Two embedded word lines 109 intersect one MC active region 103 in such a way as to divide said one MC active region 103 into three parts. The bit lines 120 extend in the X-direction, which is perpendicular to the Y-direction in the drawings. The bit lines 120 extend in such a way as to pass over the parts of the MC active regions 103 that are sandwiched between adjacent embedded word lines 109.

The bit lines 120 may be laminated bodies comprising a plurality of elements. In the mode illustrated in FIG. 2, for example, the bit lines 120 comprise, in order from the bottom, an MC polysilicon film 121, an MC laminated metal film 122 and an MC cover insulating film 123. The MC laminated metal films 122 can, for example, be laminated bodies comprising tungsten, tungsten nitride and tungsten silicide.

The first MC side walls 124 can be silicon nitride films or silicon oxynitride films, for example. The thickness of the first MC side walls 124 can be 5 nm, for example. The second MC side walls 125 can be silicon nitride films, for example. The thickness of the second MC side walls 125 can be 5 nm, for example.

The semiconductor device 100 is additionally provided with a capacitor 150 in the layer comprising the stopper film 113, the third interlayer insulating film 114 and the fourth interlayer insulating film 115. The capacitor 150 is provided with lower electrodes 151, capacitative insulating films 152 and an upper electrode 153. The capacitor 150 illustrated in FIG. 2 is a cylinder type capacitor having a plurality of bottomed cylindrical portions. The bottom portions of the bottomed cylindrical portions of the capacitor 150 are electrically connected to the MC source/drain regions 105 by way of the capacitor contact plugs 141. The capacitor 150 may also have a different shape, such as a crown shape or a fin shape.

The semiconductor device 100 is additionally provided with a wiring line 160 and an MC contact plug 154 which electrically connects the capacitor 150 to the wiring line 160.

The peripheral circuit region B will now be described. In the peripheral circuit region B, the semiconductor device 100 is additionally provided with LDD (Lightly Doped Drain) regions 106 and PC source/drain regions 107 formed in the semiconductor substrate 101, PC gate insulating films 131 formed on the semiconductor substrate 101, and PC gate electrodes 130 formed on the PC gate insulating films 131. The PC gate electrodes 130 extend in the X-direction in the drawings. In other words, the PC gate electrodes 130 extend in the same direction as (parallel to) the bit lines 120 in the memory cell region A. The PC gate electrodes 130 extend in such a way as to pass centrally through the PC active regions 104 that are aligned in the X-direction. The PC gate electrodes 130 may be laminated bodies comprising a plurality of elements. In the mode illustrated in FIG. 2, for example, the PC gate electrodes 130 comprise, in order from the bottom, a first PC polysilicon film 132, a second PC polysilicon film 133, a PC laminated metal film 134 and a PC cover insulating film 135. The PC laminated metal films 134 can, for example, be laminated bodies comprising tungsten, tungsten nitride and tungsten silicide. The PC gate insulating films 131 may be laminated bodies comprising a plurality of insulating films. The PC gate insulating films 131 may comprise a high-k film containing a high dielectric-constant material. The high-k film is preferably a film having a relative dielectric constant higher than that of a silicon nitride film. The relative dielectric constant of the high-k film is, for example, preferably at least 7. Examples of materials that can be used for the high-k film include HfO₂-based, HfSiO-based and ZrO₂-based materials. The high-k film may be a laminated body, for example formed by laminating the high-k film material with Al₂O₃, MgO or the like. The PC gate electrodes 130, the PC gate insulating films 131, the LDD regions 106 and the PC source/drain regions 107 form transistors.

The semiconductor device 100 is additionally provided with first PC side walls 136, second PC side walls 137 and third PC side walls 138 formed as side walls on both sides of the PC gate electrodes 130 and the PC gate insulating films 131. The first PC side walls 136, the second PC side walls 137 and the third PC side walls 138 are formed successively in order from the PC gate electrodes 130. The first PC side walls 136 can be silicon nitride films or silicon oxynitride films, for example. The thickness of the first PC side walls 136 can be 5 nm, for example. The second PC side walls 137 can be silicon dioxide films, for example. The thickness of the second PC side walls 137 can be 30 nm, for example. The third PC side walls 138 can be silicon nitride films, for example. The thickness of the third PC side walls 138 can be 8 nm, for example.

In the mode illustrated in FIG. 2, the semiconductor device 100 is additionally provided with PC wiring lines 143 formed in the stopper film 113, and first PC contact plugs 142 which electrically connect the PC wiring lines 143 to the PC source/drain regions 107. Further, the semiconductor device 100 is additionally provided with a second PC contact plug 155 which electrically connects a wiring line 160 to a PC source/drain region 107.

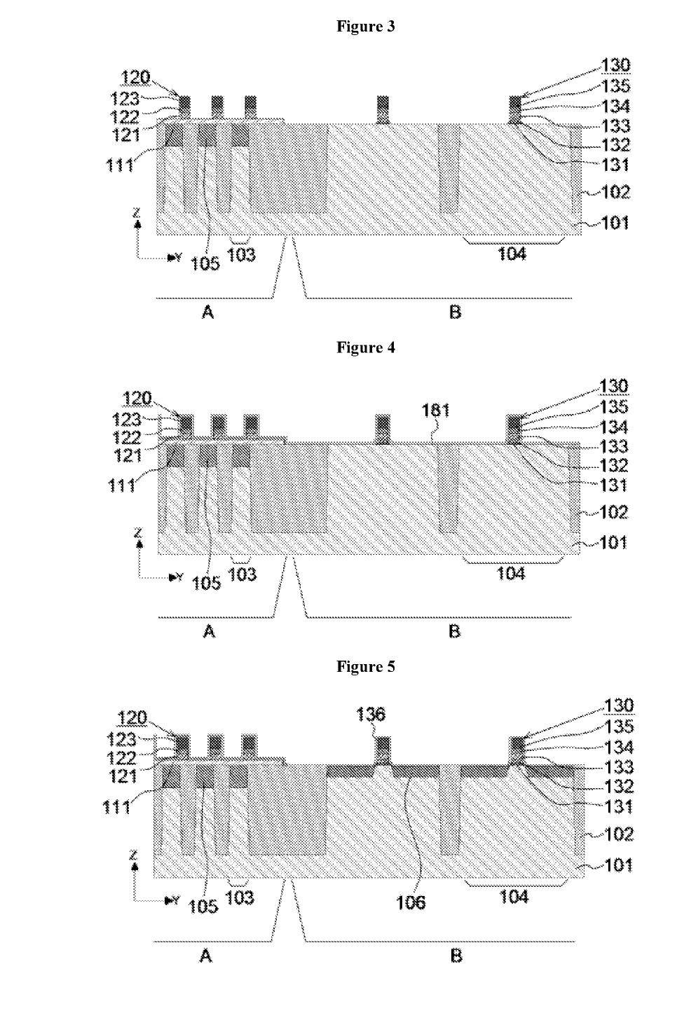

A method of manufacturing the semiconductor device according to the first mode of embodiment will now be described. FIG. 3 to FIG. 9 are schematic process diagrams used to describe the method of manufacturing the semiconductor device according to the first mode of embodiment. The element isolation regions 102 are first formed in the semiconductor substrate 101. In this way, the MC active regions 103 and the PC active regions 104 are demarcated.

In the memory cell region A, an impurity is implanted into the semiconductor substrate 101 to form the MC source/drain regions 105. Grooves (which are not shown in the drawings) are then formed in the semiconductor substrate 101. MC gate insulating films (which are not shown in the drawings) and embedded word lines (which are not shown in the drawings) are then formed in said grooves. The first interlayer insulating film 111 is then formed on the semiconductor substrate 101. Bit contact plugs (which are not shown in the drawings) which are electrically connected to the MC active regions 103 are then formed penetrating through the first interlayer insulating film 111.

In the peripheral circuit region B, the PC gate insulating films 131 are formed on the semiconductor substrate 101. The first PC polysilicon films 132 are then formed on the PC gate insulating film 131. The upper surface of the first interlayer insulating film 111 and the upper surfaces of the first PC polysilicon films 132 are made to be at the same height (they form an identical plane).

The bit lines 120 in the memory cell region A and the PC gate electrodes 130 in the peripheral circuit region B are then formed in the same step (FIG. 3). For example, a polysilicon film liner film, a laminated metal film liner film and a cover insulating film liner film are successively laminated in the memory cell region A and the peripheral circuit region B, and these are shaped into the shapes of the bit lines 120 and the PC gate electrodes 130. In this way, the polysilicon film liner film becomes the MC polysilicon layers 121 and the second PC polysilicon layers 133. The laminated metal film liner film becomes the MC laminated metal films 122 and the PC laminated metal films 134. The cover insulating film liner film becomes the MC cover insulating films 123 and the PC cover insulating films 135.

Next, in the memory cell region A and the peripheral circuit region B, a first liner film 181 is formed on the semiconductor substrate 101 in such a way as to cover the bit lines 120 and the PC gate electrodes 130 (FIG. 4). The first liner film 181 can be formed from a silicon nitride film or a silicon oxynitride film, for example. The thickness of the first liner film 181 can be 5 nm, for example.

The memory cell region A is then protected by a resist (which is not shown in the drawings). Next, in the peripheral circuit region B, the first liner film 181 is etched back to form the first PC side walls 136 as side walls on the side surfaces of the PC gate electrodes 130 and the PC gate insulating films 131. An impurity is then pocket-implanted into the semiconductor substrate 101, using the PC gate electrodes 130 and the first PC side walls 136 as a mask, to form the LDD regions 106 (FIG. 5).

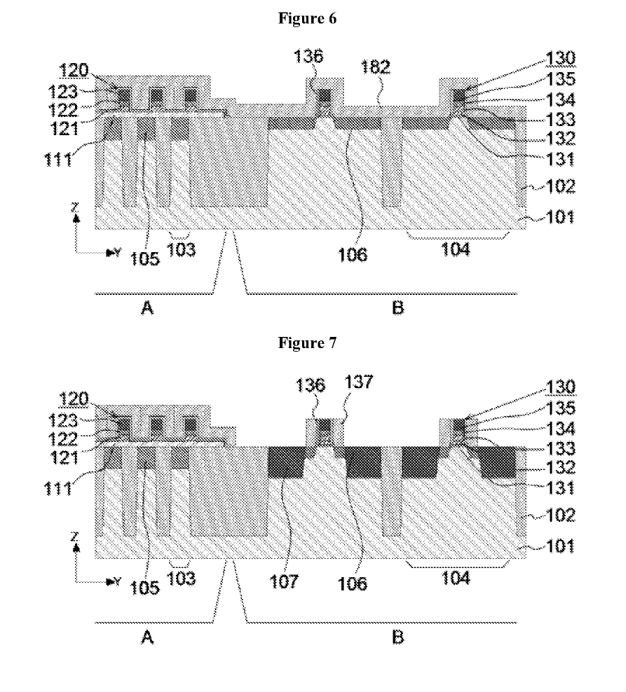

Next, in the memory cell region A and the peripheral circuit region B, a second liner film 182 is formed on the semiconductor substrate 101 in such a way as to cover the bit lines 120 and the PC gate electrodes 130 (FIG. 6). The second liner film 182 is formed in such a way as to fill the gaps between adjacent bit lines 120. The thickness of the second liner film 182 can be 30 nm, for example. The second liner film 182 can be silicon dioxide fabricated from tetraethyl orthosilicate (TEOS), for example.

The memory cell region A is then protected by a resist (which is not shown in the drawings). Next, in the peripheral circuit region B, the second liner film 182 is etched back to form the second PC side walls 137 on the outsides of the first PC side walls 136, as side walls of the PC gate electrodes 130 and the PC gate insulating films 131. An impurity is then implanted into the semiconductor substrate 101, using the PC gate electrodes 130, the first PC side walls 136 and the second PC side walls 137 as a mask, to form the PC source/drain regions 107 (FIG. 7). Heat treatment is then carried out to activate the PC source/drain regions 107. At this time, in the memory cell region A, the bit lines 120 are covered by the first liner film 181 and the second liner film 182. In the peripheral circuit region B, the PC gate electrodes 130 and the first PC side walls 136 are covered by the second PC side walls 137. Oxidation of the bit lines 120 and the PC gate electrodes 130 as a result of the heat treatment can therefore be prevented. Further, outward diffusion of the impurity implanted into the polysilicon can also be suppressed. In this way it is possible to achieve a reduction in the bit line resistance, the interfacial resistance and the resistance of the contact plugs.

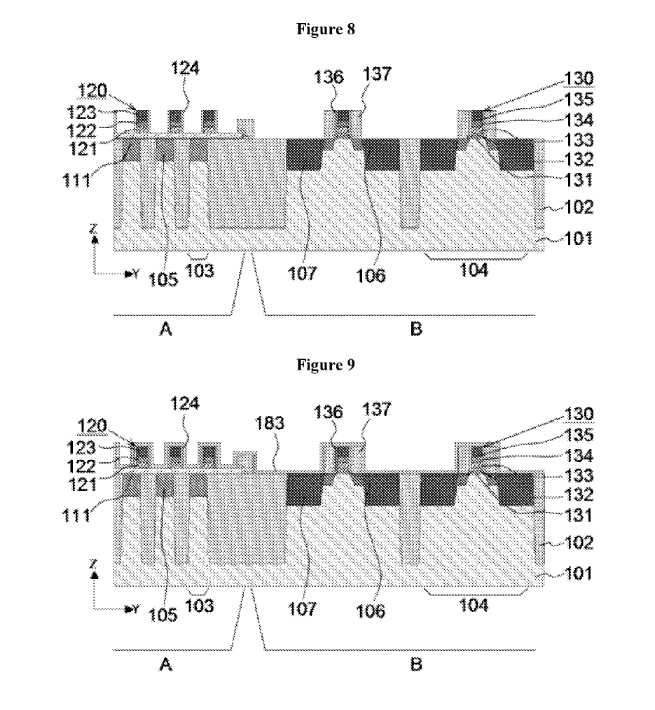

The peripheral circuit region B is then protected by a resist (which is not shown in the drawings). The second liner film 182 is then removed. The second liner film 182 can, for example, be removed by wet etching employing hydrofluoric acid or the like. The first liner film 181 in the memory cell region A is then etched back to form the first MC side walls 124 as side walls of the bit lines 120 (FIG. 8).

Next, in the memory cell region A and the peripheral circuit region B, a third liner film 183 is formed on the semiconductor substrate 101 in such a way as to cover the bit lines 120 and the PC gate electrodes 130 (FIG. 9). The third liner film 183 can be formed from a silicon nitride film, example. The thickness of the third liner film 183 can be 8 nm, for example.

The third liner film 183 is then etched back to form the second MC side walls 125 on the outsides of the first MC side walls 124, as side walls of the bit lines 120. Further, the third PC side walls 138 are formed on the outsides of the second PC side walls 137, as side walls of the PC gate electrodes 130 and the PC gate insulating films 131 (see FIG. 2). Thus the side walls of the bit lines 120 in the memory cell region A comprise the first MC side walls 124 and the second MC side walls 125. Meanwhile, the side walls of the PC gate electrodes 130 in the peripheral circuit region B comprise the first PC side walls 136, the second PC side walls 137 and the third PC side walls 138. In other words, the side walls in the peripheral circuit region B can be made thicker than the side walls in the memory cell region A by the thickness of the second PC side walls 137. Therefore, even if a high-k film is used as the PC gate insulating film 131, the EWF of the gate electrode can be fixed, and the threshold voltage can be stabilized.

The first interlayer insulating film 111 that is exposed between adjacent second MC side walls 125 is then etched in such a way as to expose the semiconductor substrate 101. The semiconductor device 100 is then manufactured by forming the second interlayer insulating film 112, the capacitor contact plugs 141, the first PC contact plugs 142, the PC wiring lines 143, the stopper film 113, the third interlayer insulating film 114, the fourth interlayer insulating film 115, the capacitor 150, the MC contact plug 154, the second PC contact plug 155, the wiring lines 160, the cover insulating film 116, and the like.

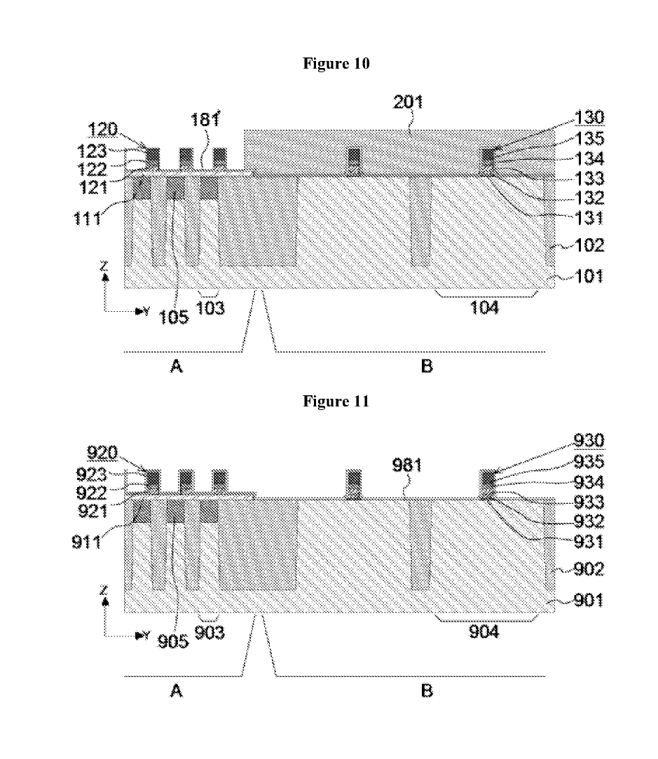

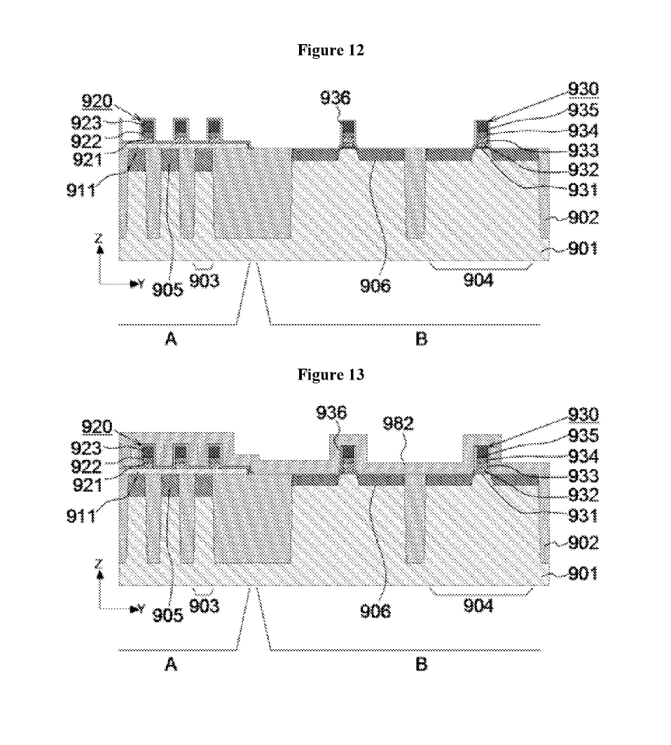

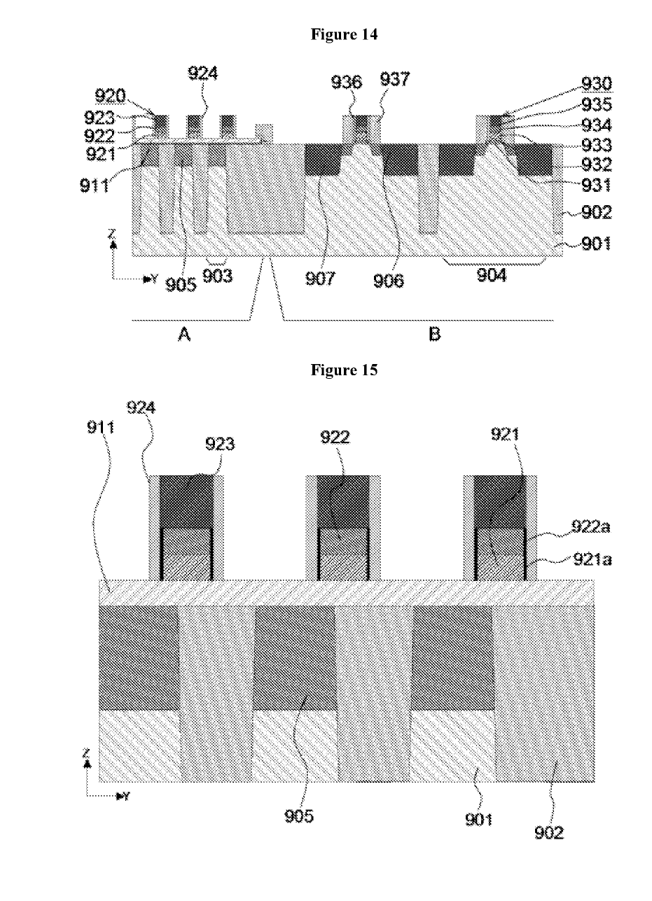

A method of manufacturing the semiconductor device according to a second mode of embodiment will now be described. FIG. 10 is a schematic process diagram used to describe the method of manufacturing the semiconductor device according to the second mode of embodiment. In the manufacturing method according to the first mode of embodiment, the thickness of the first MC side walls in the memory cell region and the thickness of the first PC side walls in the peripheral circuit region are the same. In the semiconductor device manufactured in accordance with the manufacturing method according to the second mode of embodiment, the thickness of the first MC side walls in the memory cell region is less than the thickness of the first PC side walls in the peripheral circuit region. The basic configuration of the semiconductor device according to the second mode of embodiment is the same as that of the semiconductor device according to the first mode of embodiment illustrated in FIG. 1 and FIG. 2.

The manufacturing method is the same as in the first mode of embodiment as far as the steps illustrated in FIG. 3 and FIG. 4. The peripheral circuit region B is then protected by a resist 201. The part of the first liner film 181 that is exposed in the memory cell region A is then thinned to form a thinned first liner film 181′ (FIG. 10).

Subsequent steps are the same as in the mode illustrated in FIG. 5 to FIG. 9. In other words, the manufacturing method according to the second mode of embodiment includes the step illustrated in FIG. 10, in addition to the manufacturing steps in the first mode of embodiment. In the step illustrated in FIG. 7, even though the thickness of the thinned first side wall 181′ is small, oxidation of the bit lines 120 as a result of the heat treatment can be prevented because said bit lines 120 are covered by the second liner film 182.

The same advantages can be obtained in the second mode of embodiment as in the first mode of embodiment. In addition, according to the second mode of embodiment, the thickness of the first MC side walls 124 in the memory cell region A and the thickness of the first PC side walls 136 in the peripheral circuit region B can be made to differ. In other words, the first MC side walls 124 in the memory cell region A can be thinned to the minimum necessary thickness, without being dependent on the thickness of the first PC side walls 136 in the peripheral circuit region B. In this way, the cross-sectional area of the capacitor contact plugs 141 can be maintained, and a greater reduction in the resistance of the capacitor contact plugs 141 can be achieved compared with the first mode of embodiment.

A method of manufacturing the semiconductor device according to a third mode of embodiment will now be described. In the second mode of embodiment, the step illustrated in FIG. 10 is performed before the step of etching back the first liner film 181 in the peripheral circuit region B, illustrated in FIG. 5. In the third mode of embodiment, the thinning step illustrated in FIG. 10 is performed after the step illustrated in FIG. 5. In other words, the first liner film 181 in the memory cell region A is thinned after the first liner film 181 in the peripheral circuit region B has been etched back. For example, the step of thinning the first liner film 181 in the memory cell region A may be performed before the step of forming the second liner film 182, or it may be performed after the second liner film 182 in the memory cell region A has been removed, and before the step of etching back the first liner film 181.

The same advantages can be obtained in the third mode of embodiment as in the first mode of embodiment and the second mode of embodiment.

The method of manufacturing a semiconductor device according to the present invention has been described on the basis of the abovementioned modes of embodiment, but it goes without saying that various modifications, variations and improvements to the various disclosed elements (including for example each element of each claim, each element of each mode of embodiment or example, and each element of each drawing) can be included within the scope of the present invention and on the basis of the basic technical concept of the present invention, without limitation to the abovementioned modes of embodiment. Further, various combinations of, substitutions of, or selections from the various disclosed elements (including for example each element of each claim, each element of each mode of embodiment or example, and each element of each drawing) are possible within the framework of the scope of the claims in the present invention.

Additional challenges, objectives and modes of deployment relating to the present invention will be clear from the entire disclosure of the present invention, including the scope of the claims.

With regard to ranges of numerical values set forth herein, arbitrary numerical values or sub-ranges contained within said ranges should be interpreted as being specifically set forth, even if not otherwise set forth.

### EXPLANATION OF THE REFERENCE NUMBERS

100 Semiconductor device
101 Semiconductor substrate
102 Element isolation region
103 MC active region
104 PC active region
105 MC source/drain region
106 LDD region
107 PC source/drain region
109 Embedded word line
111 First interlayer insulating film
112 Second interlayer insulating film
113 Stopper film
114 Third interlayer insulating film
115 Fourth interlayer insulating film
116 Protective insulating film
120 Bit line
121 MC polysilicon film
122 MC laminated metal film
123 MC cover insulating film
124 First MC side wall
125 Second MC side wall
130 PC gate electrode
131 PC gate insulating film
132 First PC polysilicon film
133 Second PC polysilicon film
134 PC laminated metal film
135 PC cover insulating film
136 First PC side wall
137 Second PC side wall
138 Third PC side wall
141 Capacitor contact plug
142 First PC contact plug
143 PC wiring line
150 Capacitor
151 Lower electrode
152 Capacitative insulating film
153 Upper electrode
154 MC contact plug
155 Second PC contact plug
160 Wiring line
181, 181′ First liner film
182 Second liner film
183 Third liner film
201 Resist
901 Semiconductor substrate
902 Element isolation region
903 MC active region
904 PC active region
905 MC source/drain region
906 LDD region
907 PC source/drain region
911 First interlayer insulating film
920 Bit line
921 MC polysilicon film
921a Oxidized part
922 MC laminated metal film
922a Oxidized part
923 MC cover insulating film
924 First MC side wall
925 Second MC side wall
930 PC gate electrode
931 PC gate insulating film
932 First PC polysilicon film
933 Second PC polysilicon film
934 PC laminated metal film
935 PC cover insulating film
936 First PC side wall
937 Second PC side wall
981 First liner film
982 Second liner film

1. A method of manufacturing a semiconductor device, comprising:
forming a wiring line in a first region of a semiconductor device;
forming a first gate insulating film containing a high dielectric-constant insulating material in a second region of the semiconductor device;
forming a first gate electrode on the first gate insulating film;
forming a first liner film in the first region and the second region in such a way as to cover the wiring line and the first gate electrode;
etching back the first liner film in the second region to form a first gate side wall;
forming a second liner film in such a way as to cover the first liner film in the first region and in such a way as to cover the first gate electrode in the second region;
etching back the second liner film in the second region to form a second gate side wall adjacent to the first gate side wall;
implanting a first impurity into the semiconductor substrate in the second region to form a first impurity-diffused region;
carrying out heat treatment to activate the first impurity-diffused region; and
removing the second liner film in the first region after the heat treatment has been carried out.

2. The method of claim 1, wherein at least part of the wiring line and the first gate electrode are formed using the same step.

3. The method of claim 2, wherein forming the wiring line and the first gate electrode comprises:
forming a first conductor layer on the semiconductor substrate;
forming an insulating layer on the conductor layer; and
patterning the first gate insulating film, the first conductor layer and the insulating layer into a desired shape.

4. The method of claim 1, comprising, after the first liner film has been formed, thinning the first liner film in the first region.

5. The method of claim 1, comprising, after the first gate side wall has been formed, thinning the first liner film in the first region.

6. The method of claim 1, comprising, after the second gate side wall has been formed, thinning the first liner film in the first region.

7. The method of claim 1, comprising:
etching back the first liner film in the first region to form a first wiring line side wall;
forming a third liner film on the semiconductor substrate in the first region and the second region in such a way as to cover the wiring line and the first gate electrode;
etching back the third liner film in the first region to form a second wiring line side wall adjacent to the first wiring line side wall; and
etching back the third liner film in the second region to form a third gate side wall adjacent to the second gate side wall.

8. The method of claim 7, comprising forming a first contact plug between the second wiring line side walls, electrically connected to the semiconductor substrate.

9. The method of claim 8, wherein forming the wiring line and the first gate electrode additionally comprises, before the step of forming the first conductor layer, forming a second conductor layer on the semiconductor substrate in the second region, wherein in the second region, the first conductor layer is formed on the second conductor layer.

10. The method of claim 1, comprising:
forming a first interlayer insulating film on the semiconductor substrate in the first region; and
forming a first contact plug that penetrates through the first interlayer insulating film and is electrically connected to the semiconductor substrate, wherein the wiring line is formed on the first interlayer insulating film in such a way as to be electrically connected to the first contact plug.

11. The method of claim 10, comprising after the second liner film has been removed, etching the first interlayer insulating film in such a way as to expose the semiconductor substrate.

12. The method of claim 1, comprising, after the first liner film has been formed and before forming the second liner film, implanting a second impurity into the semiconductor substrate in the second region to form a second impurity-diffused region.

13. The method of claim 1, wherein the first liner film is a silicon nitride film or a silicon oxynitride film.

14. The method of claim 1, wherein the second liner film is a silicon dioxide film.

15. The method of claim 1, comprising:
forming a groove in the semiconductor substrate in the first region;
implanting a third impurity into the semiconductor substrate in the first region to form a third impurity-diffused region;
forming a second gate insulating film in the groove; and
forming a second gate electrode on the second gate insulating film.
